(19) United States
(12) Patent Application Publication
(10) Pub. No.: US 2009/0051004 A1
(43) Pub. Date: Feb. 26, 2009

(54) Surface Mount Components Joined Between a Package Substrate and a Printed Circuit Board

(76) Inventors: Weston C. Roth, Portland, OR (US); James D. Jackson, Beaverton, OR (US); Damion Searls, Hillsboro, OR (US); Kevin Byrd, Hillsboro, OR (US)

Correspondence Address: INTEL/BSTZ;BLAKELY SOKOLOFF TAYLOR & ZAFMAN LLP, 1279 OAKMEAD PARKWAY, SUNNYVALE, CA, 94085-4040, US

(21) Appl. No.: 11/844,672

(22) Filed: Aug. 24, 2007

(51) Int. Cl. H01L 29/00; H01L 21/00; H01L 23/48

(52) U.S. Cl. 257/531; 257/738; 438/106; 257/E29.001; 257/E23.01

(57) ABSTRACT

A microelectronic package and a method of forming the package. The package includes a first level package mounted to a carrier. The first level package includes a package substrate having a die side and a carrier side; and a microelectronic die mounted on the package substrate at the die side thereof. The carrier has a substrate side, and the first level package is mounted on the carrier at the substrate side thereof. A rigid body is attached to the carrier side of the substrate at an attachment location of the substrate and to the substrate side of the carrier at an attachment location of the carrier, the attachment location of the carrier being electrically unconnected, the rigid body being configured and disposed to provide structural support between the substrate and the carrier.

### FIELD

Embodiments of the present invention relate generally to the field of microelectronic fabrication, and, in particular to a method of attaching surface mount components, such as capacitors, resistors and/or inductors, at a landside or carrier side of a package substrate.

### BACKGROUND

In FIG. 1, a conventional microelectronic package 100 is shown including a first level package 101 comprising a package substrate 102 supporting a die 104 thereon. The die 104 is shown as having been electrically and mechanically joined/bonded to the package substrate 102 by way of an array 106 of solder joints 108, and further by way of cured underfill material 110 as shown. The first level package 101 is in turn supported on and electrically and mechanically bonded to a carrier 118, such as the substrate of a printed circuit board. Carrier 118 includes carrier lands 120 thereon adapted to allow an electrical connection of the carrier 118 to additional circuitry. In turn, package substrate 102 includes substrate lands 122 on a carrier side 117 thereof adapted to allow an electrical connection of the first level package 201 to external circuitry. The lands 120 and/or 122 may include ENIG pads, for example. An array 124 of solder joints 126 is shown between the carrier lands 120 and the substrate lands 122, the solder joints 126 making up the second level interconnects. Surface mount components (hereinafter SMT) 130, such as capacitors, resistors, inductors, and the like, are shown as having been mounted on the landside of the package using for example solder 105. SMT's are typically provided for full performance power delivery. The prior art provides a standoff, as seen in FIG. 2, between the SMT's 130 and the substrate side 119 of the carrier 118. Prior art provides a standoff to prevent the SMT from contacting the carrier during a dynamic shock event and also to prevent unintentional electrical connections (i.e. shorts) between the SMT and the carrier. One advantage of the standoff is that if a sufficient gap is provided between the SMT and the carrier, then additional components (typically SMT's) can be placed on the carrier in the area directly beneath the SMT on the package substrate. However, such an arrangement is only practical in the case of socketed components, where the socket body provides a sufficiently large standoff between the SMT and the carrier.

In fact, the prior art contemplates a minimum standoff height to be provided between the SMT's and the substrate side 119 of the carrier 118. The prior art ensures the existence of the standoff by using thin SMT's, by limiting the use of SMT's to socket applications, and/or by limiting the z-height reduction and pitch reduction for BGA applications.

Disadvantageously, the use of SMT's does not adequately address the need for full performance products within markets that have strict limits on z-height and package size, including BGA pitch. In addition, as seen in FIG. 1, prior art packages including SMT's are disadvantageously prone to dynamic shock events that can cause the SMT's, such as SMT's 130 of FIG. 1, to collide with the substrate side surface 119 of the carrier 118. Dynamic shock events of the kind illustrated in FIG. 1 typically result in “Witness marks” on the carrier. These marks can directly damage features on the carrier, such as signal traces, power or ground planes, vias or surface pads. Additionally, the dynamic shock events have also been observed to damage the SMT on the package substrate. Damage to the SMT includes cracking of the components and/or of the solder attachments holding the SMT to the package substrate. The results of such a dynamic shock collision can lead to immediate failure of the components and/or of the system involved in such shock, and can, at a minimum, compromise the long term reliability of the components and system. Hence, such dynamic shock collisions are not desirable, and an adequate standoff between the SMT and carrier is typically provided to avoid such events.

The collision of the SMT's 130 is shown schematically in FIG. 1 by way of starts at the bottom portion of each SMT.

The prior art fails to provide a reliable, cost-effective package substrate structure that avoids the problems noted above.

### BRIEF DESCRIPTION OF THE DRAWINGS

FIG. 1 is a schematic, cross-sectional view of a microelectronic package undergoing a dynamic shock and including carrier side surface mount components mounted according to the prior art;

FIG. 2 is a schematic, cross-sectional view of a detail of a prior art microelectronic package such as the package of FIG. 1 prior to a dynamic shock;

FIG. 3 is a schematic, cross-sectional view of an embodiment of a microelectronic package including surface mount components jointed between the package substrate and the carrier of a PCB;

FIG. 4 is a schematic, cross-sectional view of the first level package of FIG. 3 being mounted onto the PCB barrier according to an embodiment to yield the package of FIG. 3;

FIG. 5 is a schematic, cross-sectional view of an embodiment of a system incorporating a microelectronic package as shown in FIG. 3.

For simplicity and clarity of illustration, elements in the drawings have not necessarily been drawn to scale. For example, the dimensions of some of the elements may be exaggerated relative to other elements for clarity. Where considered appropriate, reference numerals have been repeated among the drawings to indicate corresponding or analogous elements.

### DETAILED DESCRIPTION

In the following detailed description, a microelectronic package including surface mount components joined between a package surface and a carrier, such as the carrier of a PCB or motherboard, a method of forming the package, and a system including the package, are disclosed. Reference is made to the accompanying drawings within which are shown, by way of illustration, specific embodiments by which the present invention may be practiced. It is to be understood that other embodiments may exist and that other structural changes may be made without departing from the scope and spirit of the present invention.

The terms on, above, below and adjacent as used herein refer to the position of one element relative to other elements. As such, a first element disposed on, above, or below a second element may be directly in contact with the second element or it may include one or more intervening elements. In addition, a first element disposed next to or adjacent a second element may be directly in contact with the second element or it may include one or more intervening elements. In addition, in the instant description, figures and/or elements may be referred to in the alternative. In such a case, for example where the description refers to Figs. X/Y showing an element A/B, what is meant is that Fig. X shows element A and Fig. Y shows element B. In addition, a “layer” as used herein may refer to a layer made of a single material, a layer made of a mixture of different components, a layer made of various sub-layers, each sub-layer also having the same definition of layer as set forth above.

Aspects of this and other embodiments will be discussed herein with respect to FIGS. 1-5 below. The figures, however, should not be taken to be limiting, as it is intended for the purpose of explanation and understanding.

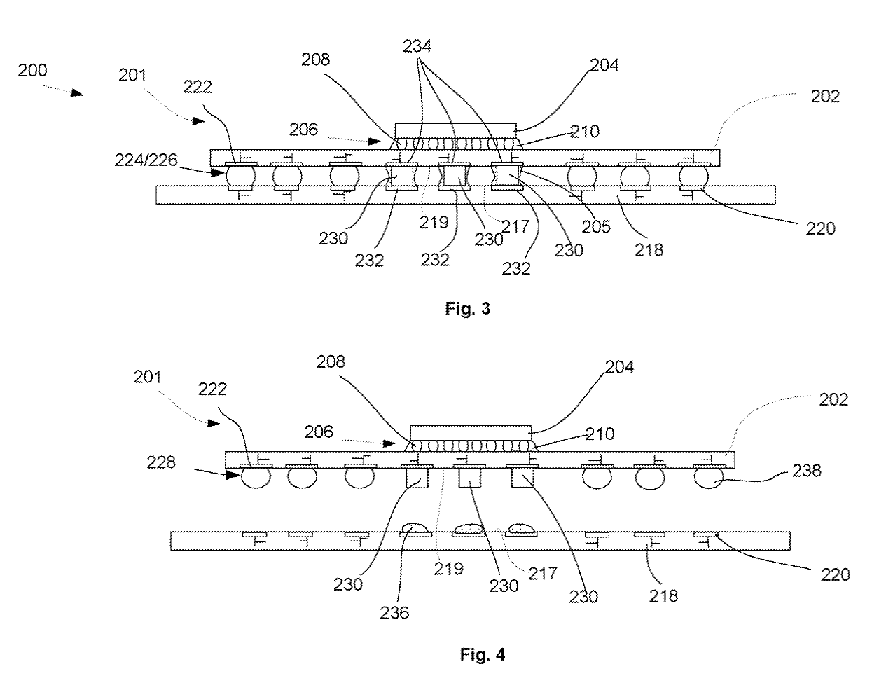

Referring first to FIG. 3, a microelectronic package 200 is shown including a first level package 201 comprising a package substrate 202 supporting a die 204 thereon. The die 204 may be electrically and mechanically joined/bonded to the package substrate 202 by way of an array 206 of solder joints 208, and further by way of cured underfill material 210 as shown. It is noted that embodiments are not limited to a flip chip or C4 connection of the die to the package substrate, and include within their ambit any type of die to package substrate connection, such as, for example by way of wire bonds, etc. The first level package 201 may in turn be supported on and electrically and mechanically bonded to a carrier 218, such as the substrate of a printed circuit board. Carrier 218 may include carrier lands 220 thereon adapted to allow an electrical connection of the carrier 218 to additional circuitry, as shown by the lines or routing layers extending into the carrier body from the lands 220. In turn, package substrate 202 may include substrate lands 222 on a carrier side 217 thereof adapted to allow an electrical connection of the first level package 201 to external circuitry, as shown by the lines or routing layers extending into the carrier body from the lands 220. The lands 220 and/or 222 may include ENIG pads, for example. An array 224 of ball grid array (BOA) solder joints 226 may be provided between the carrier lands 220 and the substrate lands 222 the solder joints 226 making up the second level interconnects. Embodiments are not limited to second level interconnects that include BGA solder joints, but comprise within their scope pin grid array (P GA) joints, or any other type of suitable second level interconnect joints as would be within the knowledge of a person skilled in the art.

Referring still to FIG. 3, embodiments include providing a rigid body that is attached to the carrier side of the substrate at an attachment location of the substrate, and to the substrate side of the carrier at an attachment location of the carrier, the attachment location of the carrier being electrically unconnected, and the rigid body being configured and disposed to provide structural support between the substrate and the carrier. In the shown embodiment, the rigid body includes a plurality of surface mount components (SMT's) 230, and solder joints 205 which serve to attach the SMT's between the substrate and the carrier. According to an embodiment, the SMT's may include capacitors, resistors, inductors, and the like. The SMT's 230 are shown as being joined or attached between the carrier side 219 of substrate 202, and the substrate side 217 of the carrier 218. The SMT's 230 in the shown embodiment are attached to the carrier side 219 of the substrate 202 at respective attachment locations 234 of the substrate, which may include respective metallic surface pads of the substrate as shown each corresponding to a substrate land 222. The attachment locations 234 of the substrate may in one embodiment include routing layers extending therefrom, and may thus be electrically connected, that is, they may provide an electrical connection through the substrate 202. The SMT's 230 are further shown as being jointed or attached to the substrate side 217 of the carrier 218 at respective attachment locations 232 of the carrier which may include respective metallic surface pads of the carrier. The attachment locations 232 do not correspond to the carrier lands 220, to the extent that, according to embodiments, they are electrically unconnected (dummy pads), that is, no routing layers or electrical connections extend through or on the carrier from carrier attachments locations 232 of the SMT's 230. Embodiments are not limited, however, to the provision of a rigid body that includes a SMT, but include within their scope any rigid body disposed between the carrier and the substrate and attached to both, where the rigid body is configured and disposed to provide structural support between the substrate and the carrier. The structural support is provided according to embodiments by virtue of the fact that the rigid body extends between the carrier and the substrate, and thus is adapted to carry loads, such as loads caused by dynamic shock, between the substrate and the carrier. According to one embodiment, as shown by way of example in FIG. 1 the rigid body may be attached, as shown in FIG. 3, at a region of the carrier side 219 of substrate 202 that is located under the die, although embodiments are not so limited, and may include the attachment of a rigid body at any location between the package substrate and the carrier.

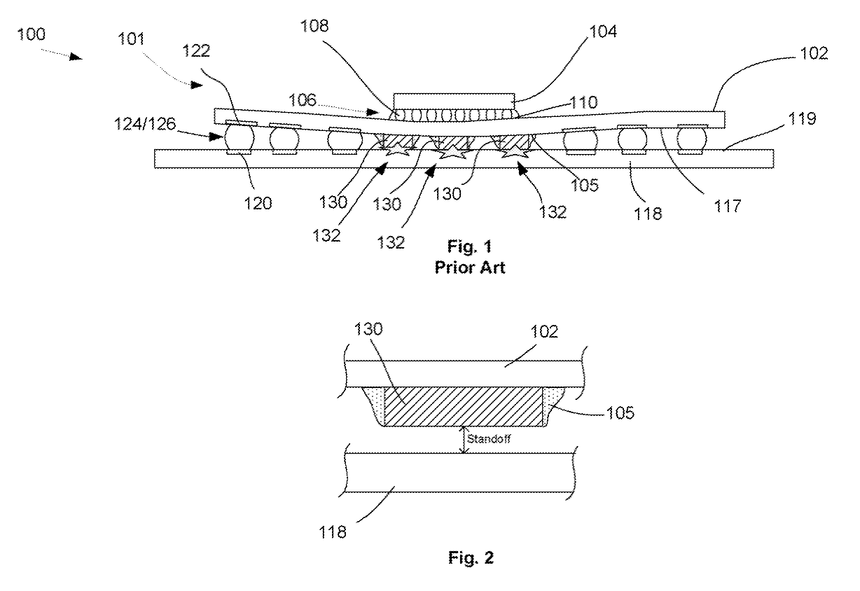

According to a method embodiment as depicted by way of example in FIG. 4, an embodiment includes providing a first level package, such as first level package 201 described above in FIG. 2, providing a carrier, such as carrier 218 of FIG. 2, mounting the first level package to the carrier, and attaching a rigid body to the carrier side of the substrate at an attachment location of the substrate, and to the substrate side of the carrier at an attachment location of the carrier. In the shown embodiment, the rigid body includes the SMT's 230 and the solder joints 205 of FIG. 2, while the attachment location of the substrate corresponds to attachment locations 234, and the attachment location of the carrier corresponds to attachment locations 232 as described above. As noted above, the attachment locations 232 are electrically unconnected. In one embodiment, the attachment locations 234 may be electrically connected to circuitry within the substrate. In the shown embodiment of FIG. 4, the first-level package 201 is a BGA package, and mounting the first-level package 201 to the carrier 218 includes attaching solder balls 238 to the BGA package at a carrier side of the substrate, to the substrate lands 222, such that a post-reflow height of the solder balls is approximately equal to a height of the SMT's 230. An exact choice of solder ball size would be determined, in addition, by component tolerances, package solder resist opening diameter and PCB pad size, as would be recognized by one skilled in the art. According to the shown embodiment of FIG. 4, the SMT's 230 may be mounted or attached to the carrier side 219 of the substrate 202 at the attachment locations 234 prior to mounting of the first level package onto the carrier. An attachment of the SMT's 230 to the BOA package may, for example, be effected by way of solder. To ensure an attachment of the SMT's 230 to the carrier, solder paste 238 may be dispensed on attachment locations 232 of carrier 218, such as, for example, by way of screen printing or any other well known method. The BGA package 201, including the SMT's thereon, may then be placed, as seen in FIG. 4, onto the carrier, such that the solder bails 238 register with corresponding lands 220 of the carrier 218, and such that the SMT's register with the solder paste 236. Thereafter the solder balls and solder paste may be reflowed in a well known manner to attach the BGA package 201 to the carrier 218, and to attach the SMT's 230 between the substrate and the carrier to obtain the rigid bodies.

Advantageously, embodiments provide a structure that avoids damage to a microelectronic package by way of dynamic shock by reinforcing a region between the package substrate and a carrier onto which the package substrate is mounted. Such reinforcement may be provided according to embodiments by way of a rigid body attached between the package substrate and the carrier, and disposed and configured to provide structural support within the package to counteract dynamic shock, A rigid body between package substrate and carrier substantially eliminates the problem of independent motion of the PCB with respect to the BGA, thus reducing the risk of landside component damage in the case of dynamic shock. In this respect, referring to Table 1 below, during dynamic shock testing, BOA packages having SMT's mounted thereon (column 3 of Table 1 marked “Proposed Technology”) according to embodiments were shown to be equivalent or better than prior art BOA packages not including SMT's (column 2 in Table 1 marked “Prior Art”), everything else being equal. As shown in Table 1, a larger shock g-force to a BOA package having a SMT mounted according to embodiments than a g-force applied to a BOA package not including a SMT brings about comparable shock micro-strains to the two packages indicating that provision of a SMT according to embodiments imparts more rigidity to a BGA package.

TABLE 1

| Package | Prior Art | Proposed Technology |
|---|---|---|
| BGA pitch | 1.27-mm | 1.27-mm |
| BGA size | 35-mil | 30-mil |
| Substrate size | 35 × 35-mm | 35 × 35-mm |
| Shock g-force | 152-g | 200-g |
| Shock micro-strain | 2537 ue | 2500 ue |

Preferably, the rigid body includes a SMT, such as a capacitor, resistor, inductor and the like, and further includes a solder joint attaching the SMT between the substrate and the carrier. Where the rigid body includes a SMT advantageously, such an embodiment enables reduced z-height and package size white maintaining full package performance. Where the first level package includes a BGA package, an embodiment where the rigid body includes a SMT further advantageously enables BGA pitch reduction. In addition, advantageously the above embodiment allows the used of carrier side SMT's in packages other than socket applications where carrier side SMT's are typically used. In addition, advantageously, leaving the attachment location of the rigid body on the carrier electrically unconnected allows a simplification of the carrier design where the rigid body is not a microelectronic component (and thus merely provides structural support), and also where the rigid body includes a SMT that is adapted to be landside or carrier side connected to the substrate. In such a case, the attachment location of the SMT on the carrier would advantageously merely serve as a structural means of attachment of the SMT to the carrier, while allowing existing SMT routing layers on the package substrate to be used for the SMT. Use of a dummy pad on the PCB carrier will also advantageously simplify the carrier design while still providing the z-height and mechanical advantages of the SMT. Thus, embodiments do not require a re-routing of conductive paths within either the package substrate or the carrier to accommodate the rigid body, such as a rigid body including a SMT.

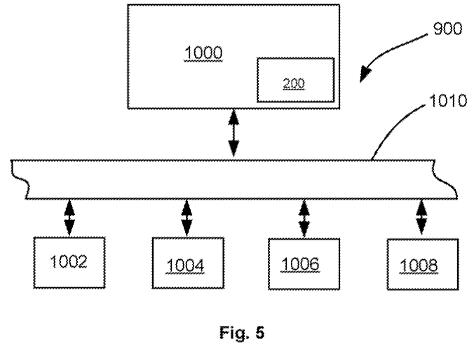

Referring to FIG. 5, there is illustrated one of many possible systems 900 in which embodiments of the present invention may be used. In one embodiment, the electronic assembly 1000 may include a microelectronic package, such as package 200 of FIG. 2. Assembly 1000 may further include a microprocessor. In an alternate embodiment, the electronic assembly 1000 may include an application specific IC (ASIC). Integrated circuits found in chipsets (e.g., graphics, sound, and control chipsets) may also be packaged in accordance with embodiments of this invention.

For the embodiment depicted by FIG. 5, the system 900 may also include a main memory 1002, a graphics processor 1004, a mass storage device 1006, and/or an input/output module 1008 coupled to each other by way of a bus 1010, as shown. Examples of the memory 1002 include but are not limited to static random access memory (SRAM) and dynamic random access memory (DRAM). Examples of the mass storage device 1006 include but are not limited to a hard disk drive, a compact disk drive (CD), a digital versatile disk drive (DVD), and so forth. Examples of the input/output module 1008 include but are not limited to a keyboard, cursor control arrangements, a display, a network interface, and so forth. Examples of the bus 1010 include but are not limited to a peripheral control interface (PCI) bus, and Industry Standard Architecture (ISA) bus, and so forth. In various embodiments, the system 90 may be a wireless mobile phone, a personal digital assistant, a pocket PC, a tablet PC, a notebook PC, a desktop computer, a set-top box, a media-center PC, a DVD player, and a server.

The various embodiments described above have been presented by way of example and not by way of limitation. Having thus described in detail embodiments of the present invention, it is understood that the invention defined by the appended claims is not to be limited by particular details set forth in the above description, as many variations thereof are possible without departing from the spirit or scope thereof.

What is claimed is:

1. A microelectronic package including:
a first level package including:
a package substrate having a die side and a carrier side,
a microelectronic die mounted on the package substrate at the die side thereof; and
a carrier having a substrate side the first level package being mounted on the carrier at the substrate side thereof;
a rigid body attached to the carrier side of the substrate at an attachment location of the substrate, and to the substrate side of the carrier at an attachment location of the carrier, the attachment location of the carrier being electrically unconnected, the rigid body being configured and disposed to provide structural support between the substrate and the carrier.

2. The package of claim 1, wherein the rigid body comprises a microelectronic surface-mount component.

3. The package of claim 2, wherein the surface-mount component includes one of a capacitor, a resistor and an inductor.

4. The package of claim 2, wherein the rigid body further includes a solder joint attaching the surface-mount component to the attachment location of the substrate and to the attachment location of the carrier.

5. The package of claim 1, wherein the rigid body is attached at a region of the carrier side located under the die.

6. The package of claim 1 further including second-level interconnects connecting the first-level package to the carrier, the second level-interconnects including one of a BGA and a PGA.

7. The package of claim 2, wherein
the attachment location of the substrate includes a metallic surface pad of the substrate, the surface-mount component being electrically connected to the substrate via the metallic surface pad of the substrate;
the attachment location of the carrier includes a metallic surface pad of the carrier that is electrically unconnected.

8. A method of providing a microelectronic package comprising:
providing a first level package including:
a package substrate having a die side and a carrier side,
a microelectronic die mounted on the package substrate at the die side thereof; and
providing a carrier having a substrate side;
mounting the first-level package to the carrier on the substrate side thereof;
attaching a rigid body to the carrier side of the substrate at an attachment location of the substrate, and to the substrate side of the carrier at an attachment location of the carrier, the attachment location of the carrier being electrically unconnected, the rigid body being configured and disposed to provide structural support between the substrate and the carrier.

9. The method of claim 8, wherein the rigid body includes a microelectronic surface-mount component.

10. The method of claim 9, wherein attaching a rigid body includes:
attaching the surface-mount component to the carrier side of the substrate at the attachment location of the substrate; and
while mounting the first-level package to the carrier, attaching the rigid body to the substrate side of the carrier at the attachment location of the carrier.

11. The method of claim 10, wherein the first-level package is a BOA package, and wherein mounting the first-level package to the carrier includes:
attaching solder balls to the BGA package at a carrier side of the substrate such that a post-reflow height of the solder balls is approximately equal to a height of the surface-mount component;
applying solder paste to the attachment location on the carrier,
placing the BOA package including the surface-mount component thereon onto the carrier such that the solder balls register with corresponding lands of the carrier, and such that the surface-mount component registers with the solder paste; and
reflowing the solder balls and solder paste to attach the BOA package to the carrier and to attach the surface-mount component between the substrate and the carrier to obtain the rigid body.

12. The package of claim 9, wherein the surface-mount component includes one of a capacitor, a resistor and an inductor.

13. The package of claim 9, wherein the rigid body further includes a solder joint attaching the surface-mount component to the attachment location of the substrate and to the attachment location of the carrier.

14. The package of claim 1, wherein the rigid body is attached at a region of the carrier side located under the die.

15. The package of claim 1, wherein mounting the first-level package to the carrier includes providing second-level interconnects to connect the first-level package to the carrier, the second level-interconnects including one of a BGA and a PGA.
